(19) United States
(12) Patent Application Publication
(10) Pub. No.: US 2026/0143609 A1
(43) Pub. Date: May 21, 2026

(54) PROTECTIVE CASE FOR HEARING AIDS

(71) Applicant: HEAR2HELP INDUSTRIES LLC., Lincoln, NE (US)

(72) Inventor: Sophia Stockham, Lincoln, NE (US)

(21) Appl. No.: 19/392,819

(22) Filed: Nov. 18, 2025

Related U.S. Application Data
(60) Provisional application No. 63/721,603, filed on Nov. 18, 2024.

(51) Int. Cl. H05K 5/03; H04R 25/00

(52) U.S. Cl. CPC H05K 5/03; H04R 25/65; H04R 2225/021

(57) ABSTRACT

A protective cover for a hearing aid component is provided. The cover includes a first housing member configured to receive the hearing aid component and a second housing member configured to receive the first housing member with the hearing aid component. The first and second housing members cooperate to protect the hearing aid component from damage, such as mechanical shock, moisture ingress, and debris, while maintaining acoustic and electronic functionality of the hearing aid component. The first housing member is formed of a flexible material and includes a lattice portion for improving drop protection while the second housing member is formed of a hard material for protecting the hearing aid component from damage. A hearing aid system and a method of protecting a hearing aid component is also provided.

### CROSS-REFERENCE TO RELATED APPLICATIONS

This application claims the benefit of U.S. Provisional Application No. 63/721,603, filed on November 18, 2024. The entire disclosure of the above application is incorporated herein by reference.

### FIELD

The present technology relates to hearing aid accessories and protective equipment, and, more particularly, to protective covers for behind-the-ear hearing aid components.

### INTRODUCTION

This section provides background information related to the present disclosure which is not necessarily prior art.

Hearing loss may involve a partial or total inability to hear sounds. Hearing loss may be classified into two main categories: conductive and sensorineural hearing loss. Conductive hearing loss occurs when the normal mechanical pathway of an outer and middle ear are impeded, resulting in sound being blocked from reaching the inner ear, while sensorineural hearing loss results from damage to an inner ear or nerve pathway from the inner ear to the brain, which affects how sound is processed. An individual with conductive hearing loss may retain residual hearing capabilities and may benefit from auditory prostheses, such as a behind-the-ear (BTE) hearing aid, an acoustic hearing aid, a bone conduction device, and a direct acoustic stimulator.

The BTE hearing aid may sit behind an ear of the individual and deliver sound through a tube or wire into an earmold. The earmold may be connected to an amplifier and include certain control functions. This externally worn device may house sensitive electronic components including a microphone, an amplifier, a controller, and battery within a protective case. However, the BTE hearing aid case is not hermetically sealed and may include various openings and gaps adjacent to the control functions such as the volume control wheels, on/off switches, and battery compartment doors. This makes the BTE hearing aid vulnerable to environmental hazards, which may compromise the integrity of the hearing aid and require costly repairs.

Environmental conditions may also compromise the integrity of the BTE hearing aid. Exposure to moisture from ambient humidity, precipitation, perspiration, and water from bathing or swimming may pose a risk to the internal circuitry. Contaminants such as dust, hair care products, and other substances may also infiltrate the hearing aid device through the openings and cracks. Such exposure may lead to corrosion of internal components and switches, resulting in device malfunction and requiring expensive repairs or complete replacement.

Certain protective solutions for hearing aid devices may have one or more drawbacks. A protective case may utilize a rigid material that provides limited comfort to the individual and may fail to address the anatomical variations among individuals with hearing loss. Other protective solutions may employ single-layer construction that offers insufficient protection against impact damage and moisture ingress, each of which may affect the integrity of the hearing aid device. Additionally, certain protective solutions may lack customization features that would accommodate the specific anatomical characteristics of the ear structure of the individual, resulting in poor fit and reduced comfort during extended wear.

There is a continuing need for an improved protective cover for a hearing aid component that provides enhanced protection against moisture and environmental contaminants while offering a customized fit based on the individual user anatomy, incorporates multiple protective layers including impact-resistant features, and maintains compatibility with hearing aid functionality including access to microphones and charging ports.

### SUMMARY

In concordance with the instant disclosure, an improved protective cover for a hearing aid component that provides enhanced protection against moisture and environmental contaminants while offering a customized fit based on the individual user anatomy, incorporates multiple protective layers including impact-resistant features, and maintains compatibility with hearing aid functionality including access to microphones and charging ports, has surprisingly been discovered. The present technology includes articles of manufacture, systems, and processes that relate to protective covers for hearing aid components.

In certain embodiments, a cover for a hearing aid is provided. The cover may include a first housing member configured to receive the hearing aid component. The hearing aid component may be a behind-the-ear hearing aid component. The cover may also include a second housing member configured to receive the first housing member with the hearing aid component. The first housing member and the second housing member may militate against damage to the hearing aid component while maintaining functionality of the hearing aid component.

In certain embodiments, a hearing aid system is provided. The hearing aid system may include a cover for a hearing aid component including the first housing member and the second housing member. The hearing aid system may also include a hearing aid component.

In certain embodiments, a method of protecting a hearing aid component is provided. The method may include a step of providing a hearing aid component, providing a cover for a hearing aid component, disposing the behind-the-ear hearing aid component within the first housing member, and disposing the first housing member with the behind-the-ear hearing aid component within the second housing member.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a top perspective view of a cover for a hearing aid component including a first housing member and a second housing member, according to an embodiment of the present disclosure.

FIG. 2 is a perspective view of a second housing member shown in FIG. 1.

FIG. 3 is a bottom plan view of the second housing member shown in FIG. 2.

FIG. 4 is a top plan view of the second housing member shown in FIG. 2.

FIG. 5 is a right-side elevational view of the second housing member shown in FIG. 2.

FIG. 6 is a rear elevational view of the second housing member shown in FIG. 2.

FIG. 7 is a front elevational view of the second housing member shown in FIG. 2.

FIG. 8 is a perspective view of a first housing member shown in FIG. 1.

FIG. 9 is a bottom plan view of the first housing member shown in FIG. 8.

FIG. 10 is a top plan view of the first housing member shown in FIG. 8.

FIG. 11 is a right-side elevational view of the first housing member shown in FIG. 8.

FIG. 12 is a rear elevational view of the first housing member shown in FIG. 8.

FIG. 13 is a front elevational view of the first housing member shown in FIG. 8.

FIG. 14 is an exploded view of a hearing aid system, according to another embodiment of the present disclosure, illustrating the first housing member and the second housing member of the cover and the hearing aid component.

FIG. 15 is a perspective view of the hearing aid system shown in FIG. 14, illustrating an assembly of the cover including the first housing member and the second housing member with the hearing aid component.

FIG. 16 is an environmental view of the hearing aid system, as worn on an ear of an individual.

FIG. 17 is a flowchart illustrating a method of protecting a hearing aid component, according to yet another embodiment of the present disclosure.

### DETAILED DESCRIPTION

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments, including where certain steps can be simultaneously performed, unless expressly stated otherwise. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1–10, or 2–9, or 3–8, it is also envisioned that Parameter X may have other ranges of values including 1–9, 1–8, 1–3, 1–2, 2–10, 2–8, 2–3, 3–10, 3–9, and so on.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

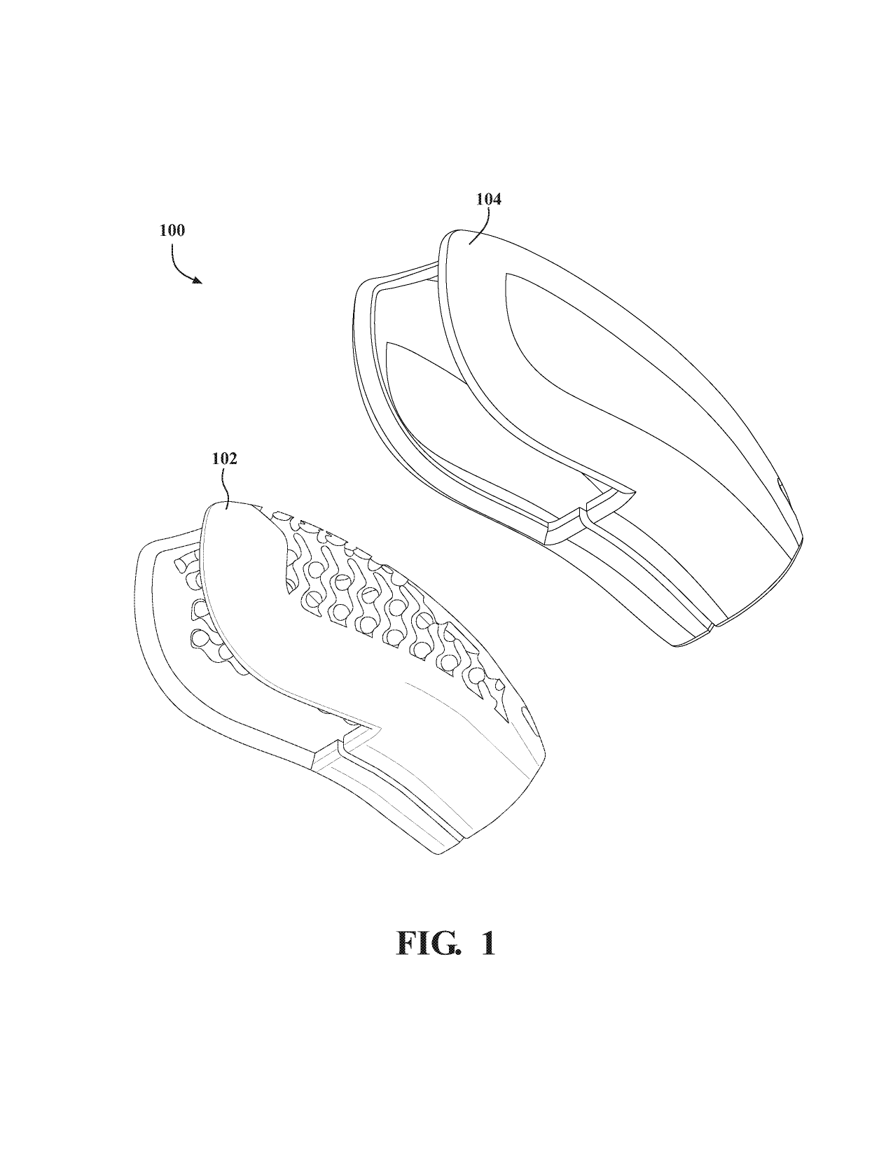

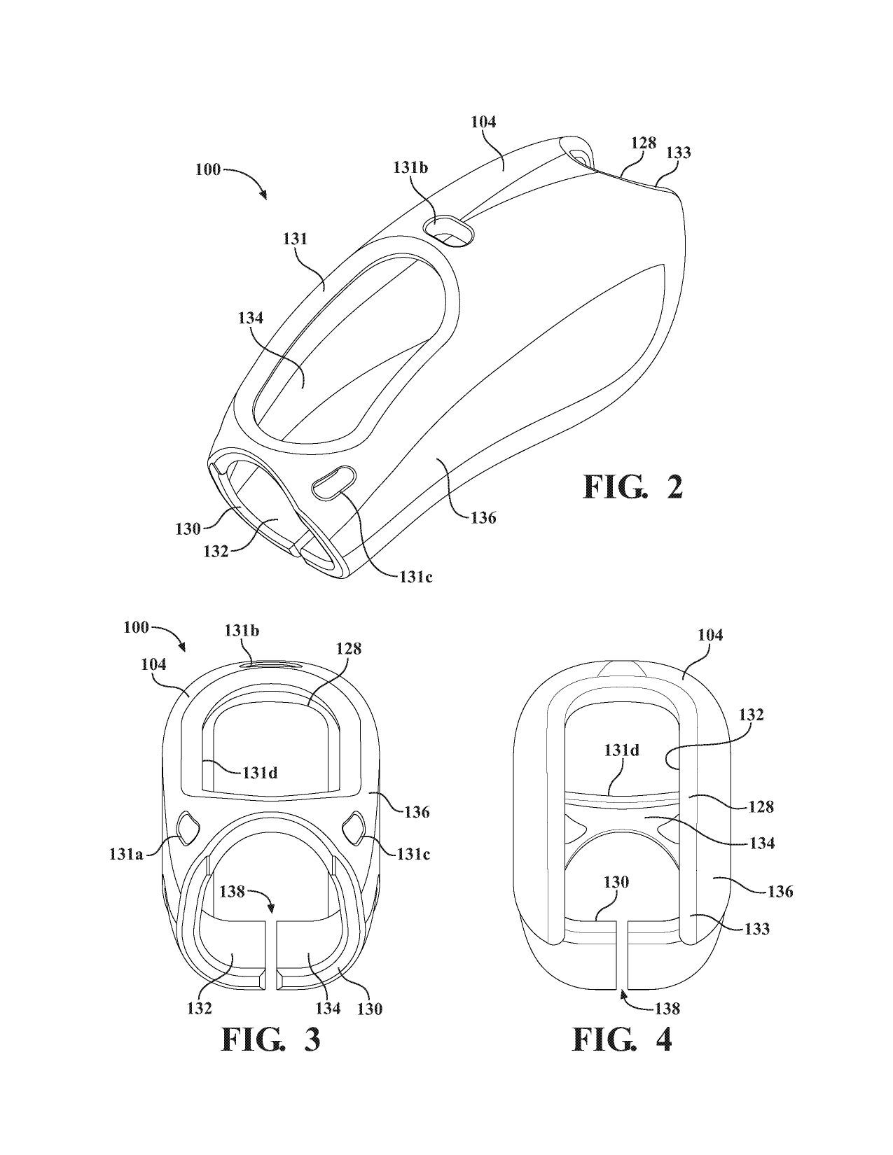

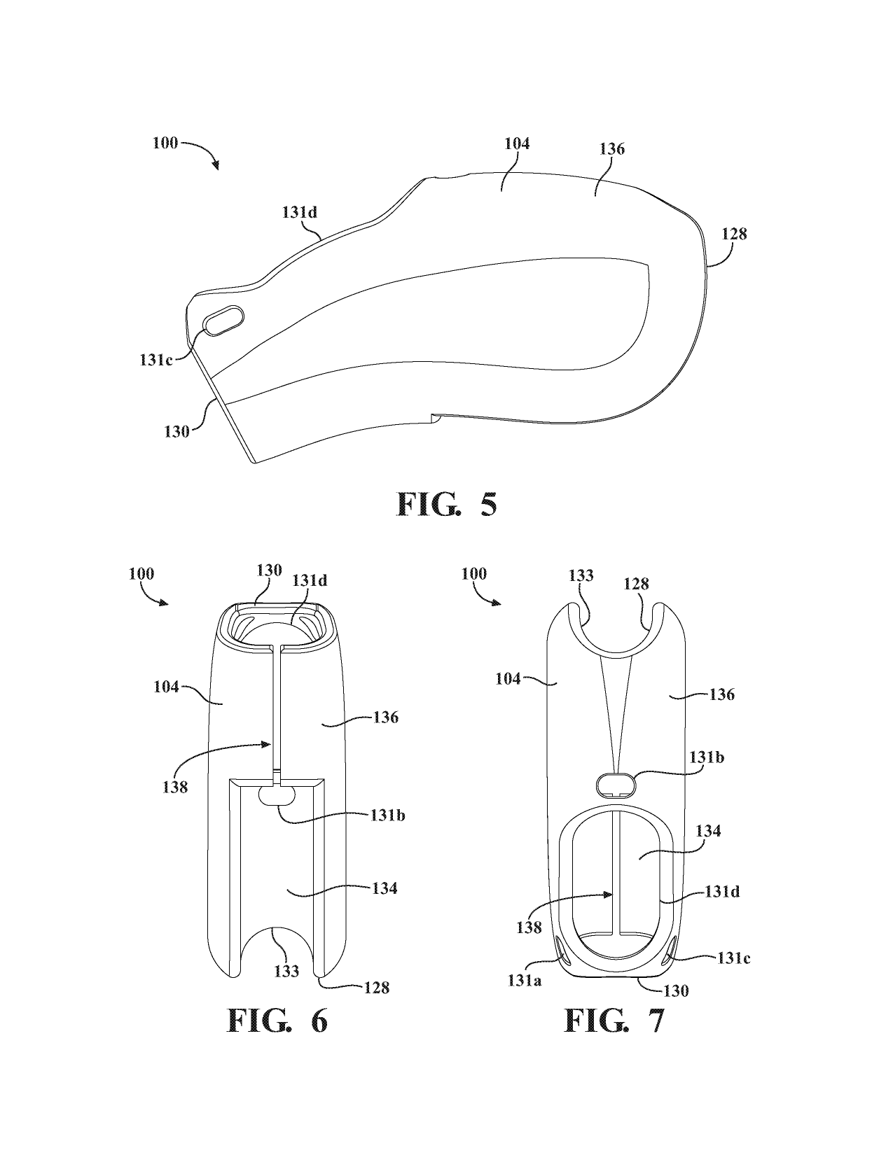

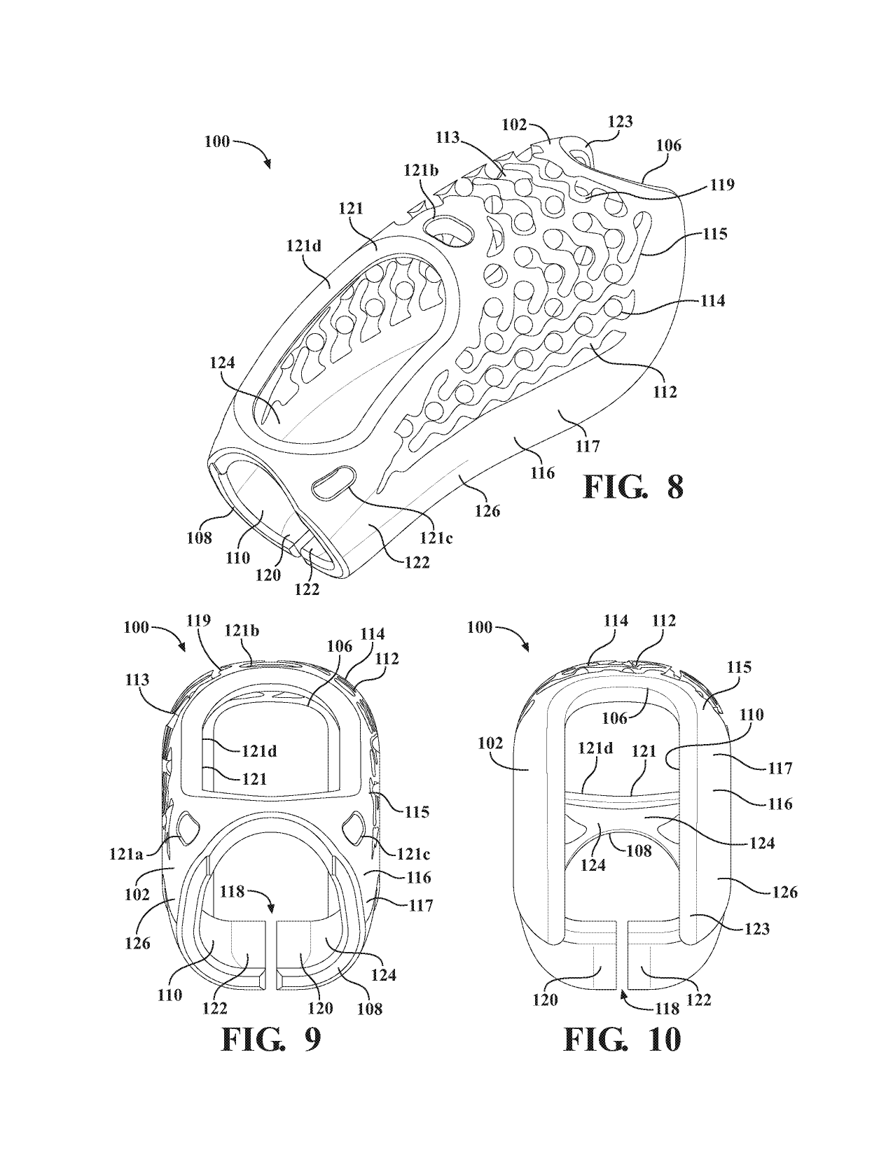

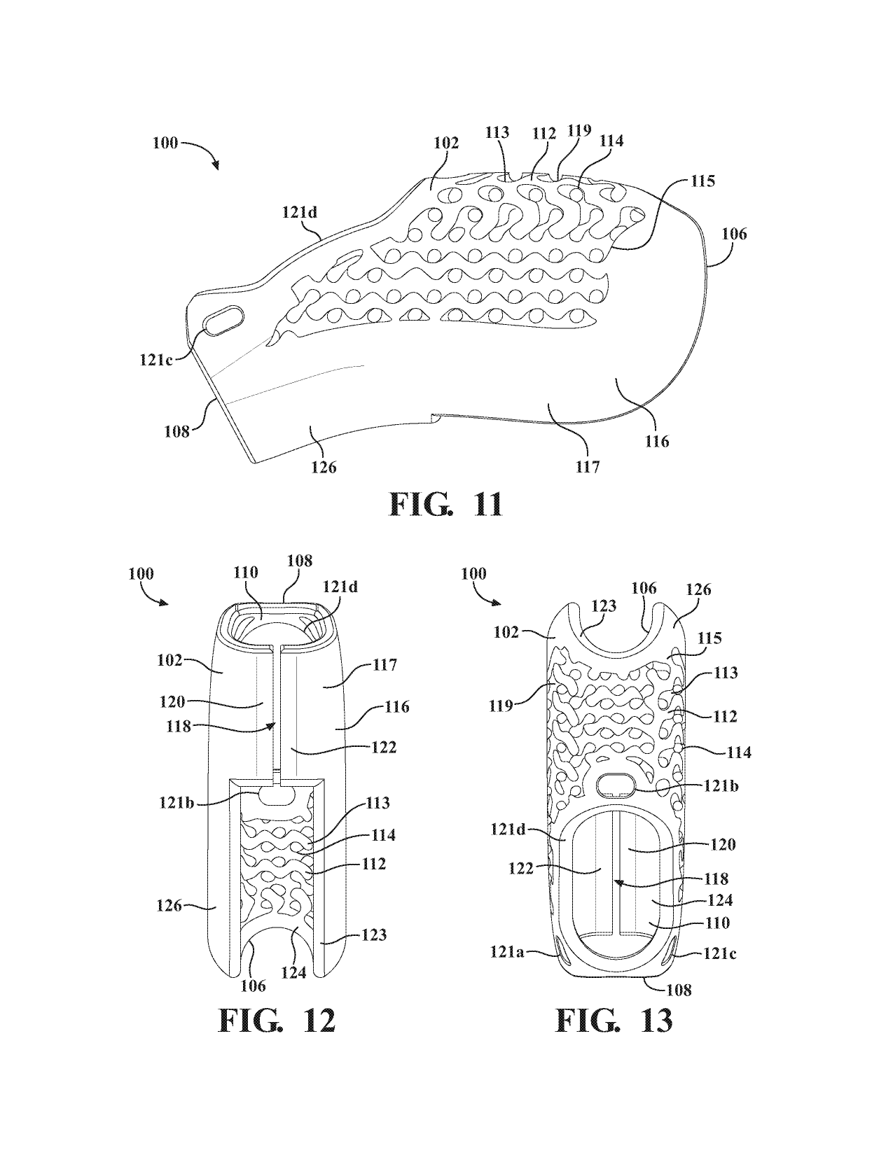

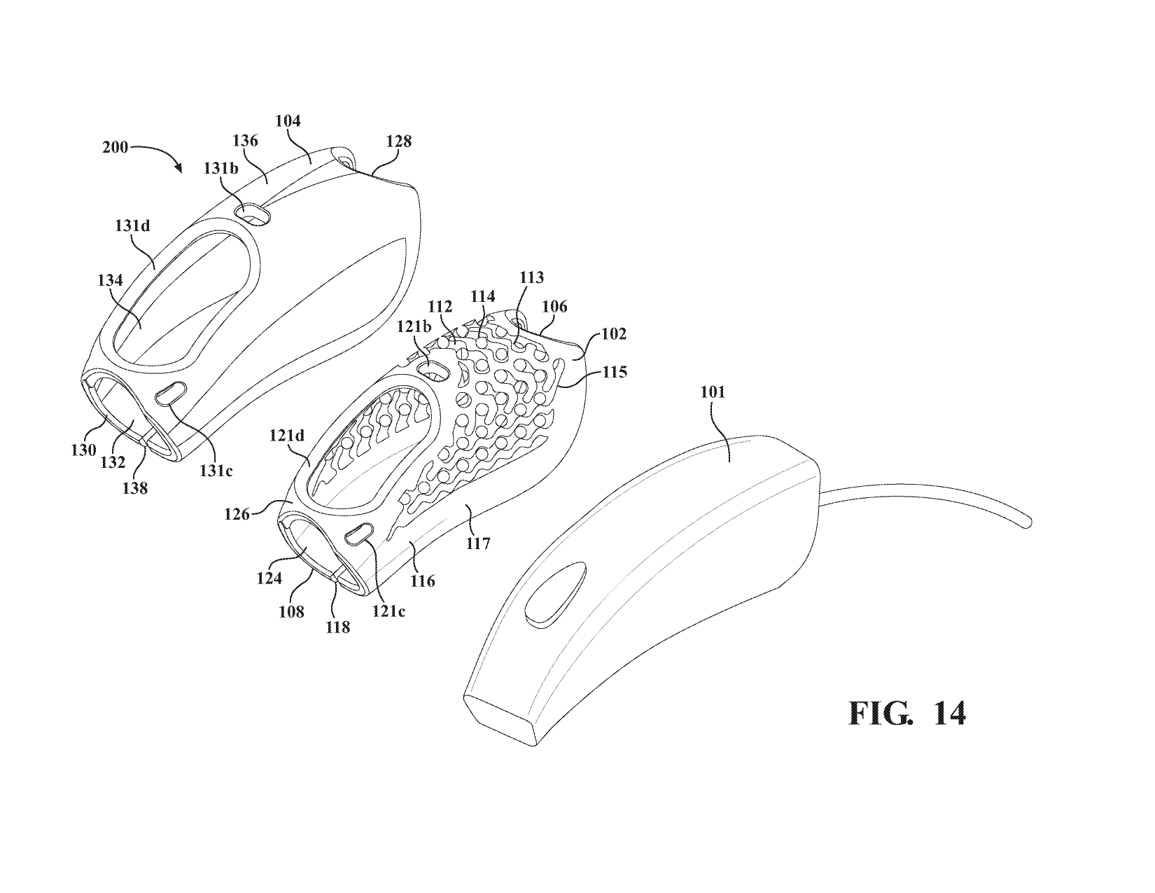

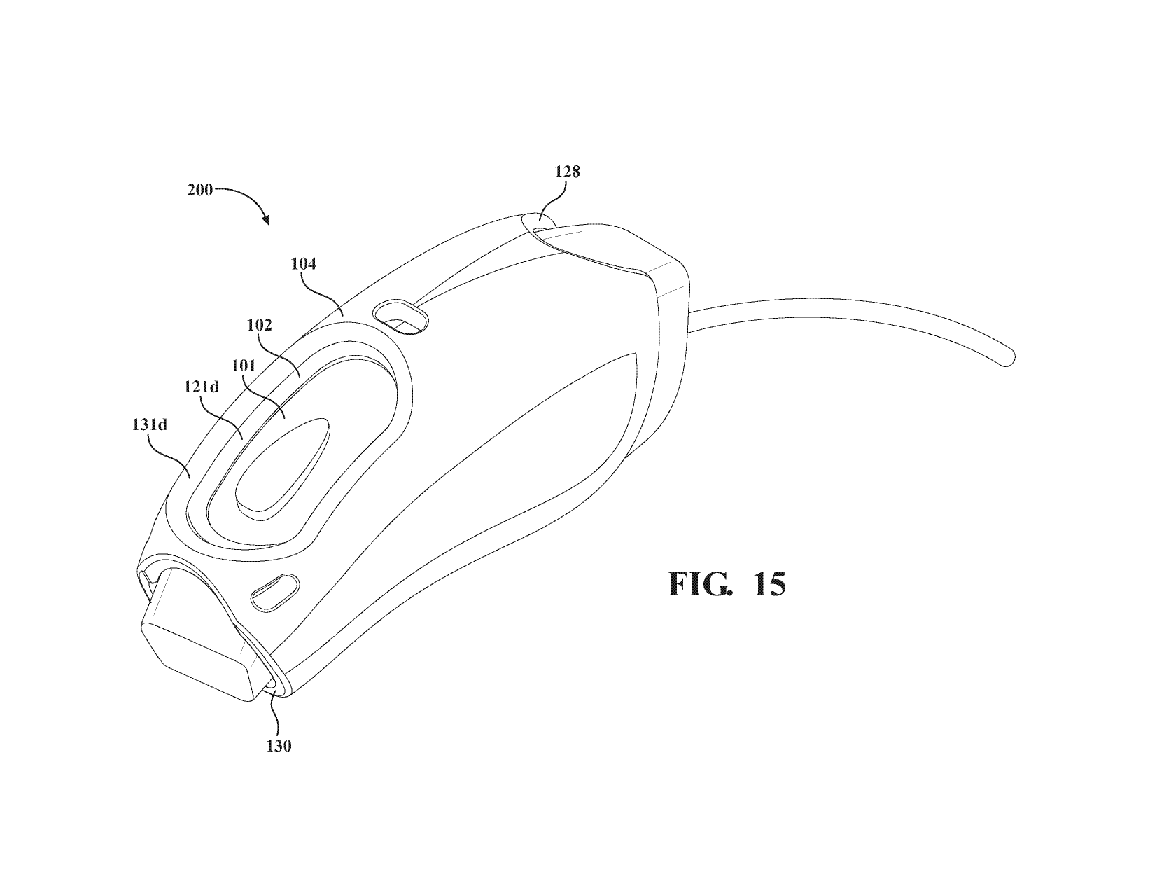

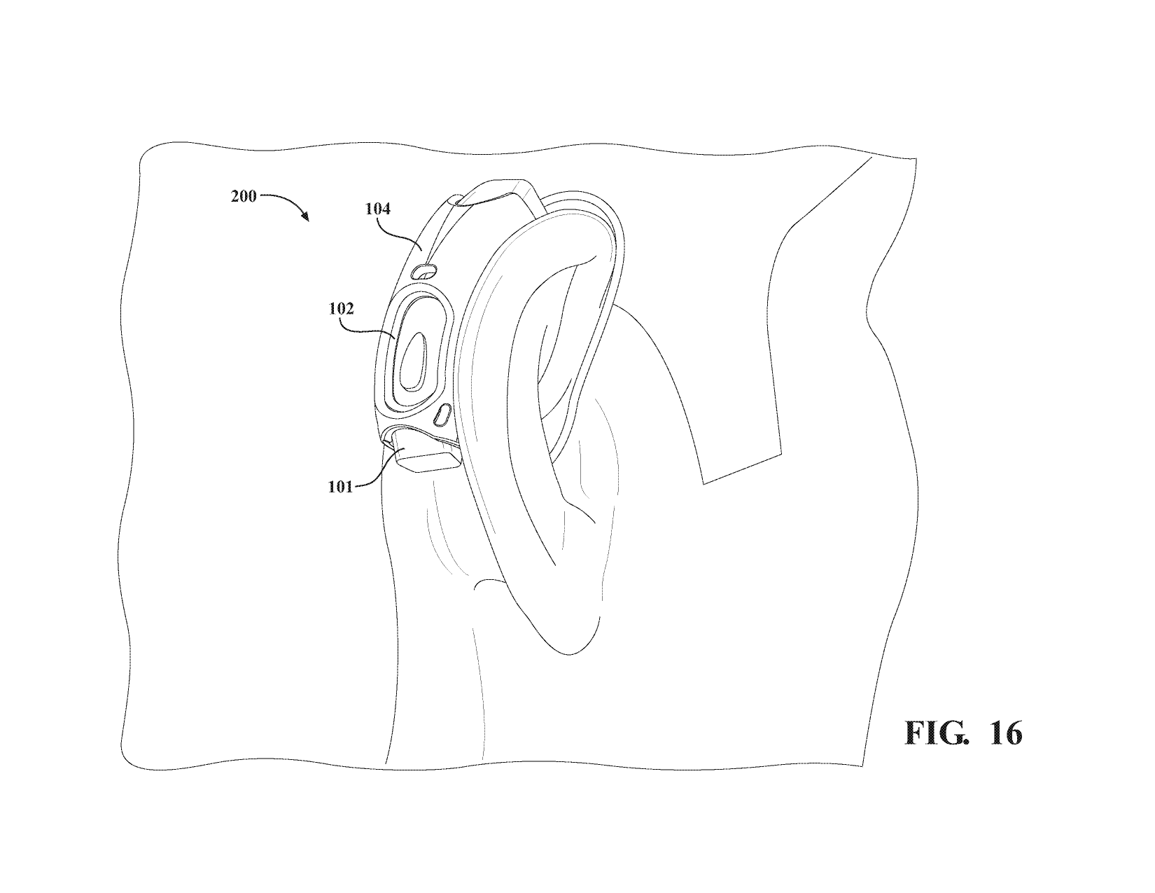

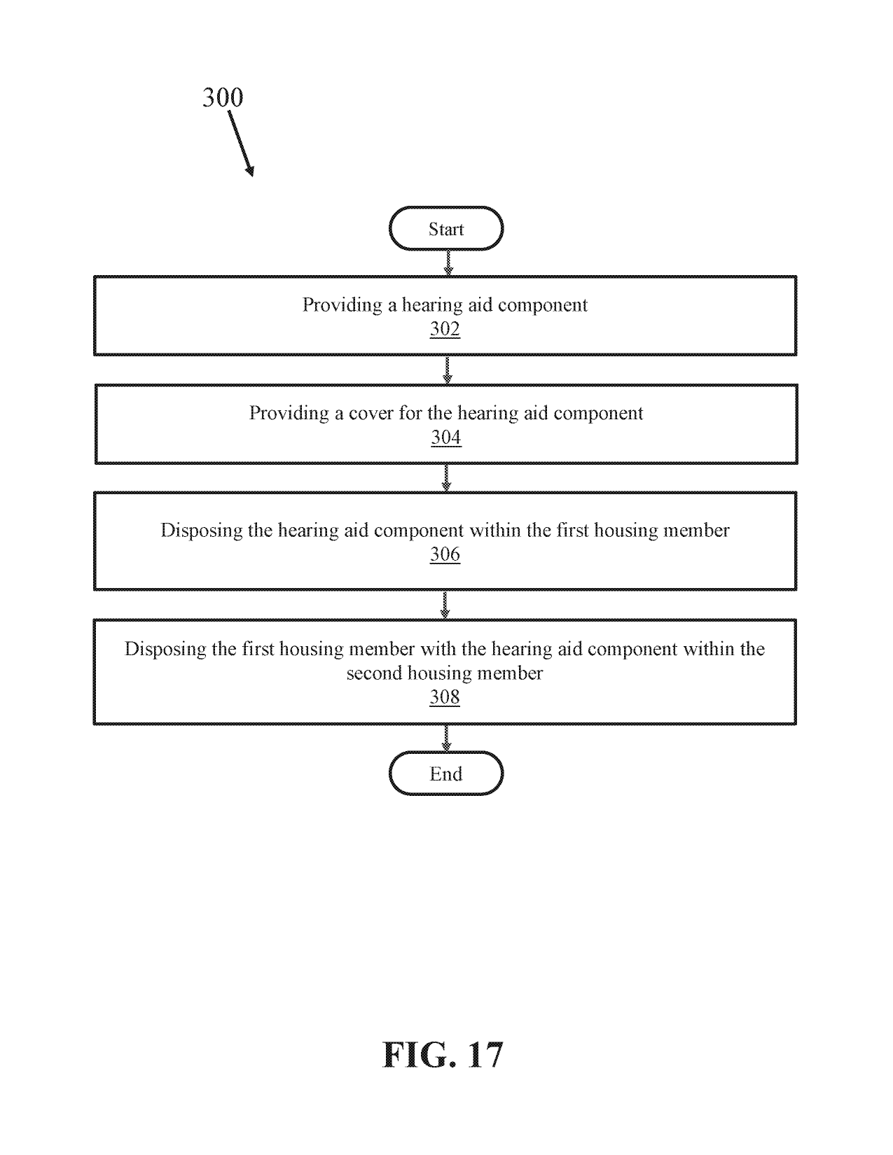

With reference to FIGS. 1-13, an embodiment of a cover 100 for a hearing aid component 101 is provided. An embodiment of a hearing aid system 200 is also provided, as shown in FIGS. 14-16. An embodiment of a method 300 of protecting a hearing aid component 101 is further provided, as shown in FIG. 17.

With particular reference to FIGS. 1-13, the cover 100 for the hearing aid component 101 may be configured to protect the hearing aid component 101 from damage to external environments and environmental conditions such as humidity, heat, dust, water, and moisture, by housing the hearing aid component 101 within the cover 100. Advantageously, the cover 100 may protect the hearing aid component 101 from damage from the surrounding environment or damage from accidents or misuse that may impact the hearing aid component 101.

The hearing aid component 101 may be a behind-the-ear hearing aid component 101, although the cover 100 may be adapted for other hearing aid components not limited to behind-the-ear hearing aid components. It should be noted that the behind-the-ear hearing aid component 101 may be understood to define a device to accommodate hearing loss of an individual where the device includes a hard plastic case that may rest behind the ear of the individual and contain electronic components connected by a thin tube or wire to an earmold that sits inside the ear canal. The behind-the-ear hearing aid component 101 may include a microphone, an amplifier, and a speaker (not shown). The microphone may pick up sound from a surrounding environment. The amplifier may increase the strength or volume of the sound and may adjust the sound based on the individual and the extent of the hearing loss of the individual. The speaker may send the amplified sound into the ear through the earmold which sits inside the ear canal, allowing the sound to be delivered directly to the ear canal. The thin tube or wire may connect the behind-the-ear hearing aid component 101 to the earmold in the ear canal. The behind-the-ear hearing aid component 101 may also include additional controls or wireless features for program settings, volume, or other connectivity. One of ordinary skill in the art may configure the cover 100 for removably coupling to various types, shapes, and parts of a hearing aid component 101, as well as to portions thereof.

The cover 100 may include a first housing member 102 and a second housing member 104 configured to define the cover 100 for the hearing aid component 101. The first housing member 102 and the second housing member 104 may militate against damage to the hearing aid component 101 while maintaining functionality of the hearing aid component 101. The first housing member 102 may be formed from a flexible material, such as an elastomeric polyurethane (EPU) material. The EPU material may also be EPU 40, which is a three-dimensional printable polyurethane elastomeric material that may include tear strength, tear resistance, and high elasticity, particularly suitable for receiving the hearing aid component 101. The flexibility in the EPU 40 allows the first housing member 102 to receive the hearing aid component 101 and militate against damage to the hearing aid component 101 while still securing the hearing aid component 101 therein. One of ordinary skill in the art may select a suitable material to form the first housing member 102 within the scope of the present disclosure.

As shown in FIGS. 1 and 8-13, the first housing member 102 may include a first end 106 and a second end 108. Each of the first end 106 and the second end 108 may be open ends forming a first channel 110 therebetween. The first end 106 and the second end 108 may allow the hearing aid component 101 to be slidably received through the first channel 110 of the first housing member 102 for securing the hearing aid component 101 within the first housing member 102. The first end 106 may be larger or greater in one or more dimensions than the corresponding dimensions of the second end 108, thereby facilitating the hearing aid component 101 to be slidably received within the first housing member 102 from the first end 106 until contacting the second end 108. More specifically, the first end 106 may include a larger diameter than a diameter of the second end 108, allowing the second end to secure the hearing aid component 101 and militate against the hearing aid component 101 from sliding out of the second end 108. The first housing member 102 may include interior dimensions substantially equal to exterior dimensions of the hearing aid component 101 for providing the secure coupling thereof. The first housing member 102 may, therefore, be customized to accommodate a shape of the hearing aid component 101 according to the interior dimensions thereof and may also take into account the shape of the ear of the individual for comfort in configuring the exterior dimensions of the first housing member 102.

With continued reference to FIGS. 1 and 8-13, the first housing member 102 may include a lattice portion 112 having a plurality of interconnected apertures 114 disposed through the first housing member 102. The lattice portion 112 having the interconnected apertures 114 may be disposed through a portion 115 of the first housing member 102. The interconnected apertures 114 may be interconnected via grooves 113. The grooves 113 may connect the interconnected apertures 114 along the portion 115 of the first housing member 102. The interconnected apertures 114 may pass from an outer surface 126 of the first housing member 102 to an inner surface 124 of the first housing member 102 such that the grooves 113 may provide a recessed surface 119 along the portion 115 of the first housing member 102. The recessed surface 119 may run through the outer surface 126 so that the grooves 113 connect each of the interconnected apertures 114 to one another from the outer surface 126 to the inner surface 124 of the first housing member 102. Advantageously, the lattice portion 112 with the interconnected apertures 114 may be configured to improve drop protection and shock absorption. Drop protection may be provided by the lattice portion 112 protecting the hearing aid component 101 from damage if the cover 100 with the hearing aid component 101 were to accidentally be dropped. The lattice portion 112 may also include shock absorption capabilities where if the cover 100 with the hearing aid component 101 were accidentally dropped or mishandled, the lattice portion 112 may absorb and reduce the impact of the force to the hearing aid component 101, protecting the overall integrity of the hearing aid component 101. One of ordinary skill in the art may select a suitable lattice portion 112 configuration within the scope of the present disclosure.

The first housing member 102 may also include another portion 117 having a smooth surface 116. The smooth surface 116 may be disposed adjacent the lattice portion 112. It should be appreciated that the smooth surface 116 particularly does not include any surface interruptions and is relatively smooth to assist in and facilitate slidably coupling to the second housing member 104, as described herein, where the first housing member 102 is received within the second housing member 104.

The smooth surface 116 may further be separated by a first gap 118. The first gap 118 may be configured as a break or discontinuity of the first housing member 102. The first gap 118 may have a surface alteration 120 surrounding the first gap 118, as further described herein. The surface alteration 120 surrounding the first gap 118 may include a plurality of ridges 122 disposed along the inner surface 124 and the outer surface 126 of the first housing member 102. The ridges 122 may surround an entirety of the first gap 118 on both the inner surface 124 and outer surface 126 of the first housing member 102. The ridges 122 may be configured to position and align the first housing member 102 with the second housing member 104, as further described herein. The surface alteration 120 may alternatively be a plurality of protuberances, grooves, divots, or any other surface alteration or combination thereof for allowing the first housing member 102 to be secured and aligned within the second housing member 104 within the scope of the present disclosure. The ridges 122 may be disposed on the inner surface 124 the first channel 110 of the first housing member. The ridges 122 may also be disposed on the outer surface 126 of the first housing member 102 adjacent the smooth surface 116.

The first housing member 102 may also include one or more openings 121. The opening 121 may be configured to expose a feature or component of the hearing aid component 101 including a button, a speaker, a microphone, audible receiver, amplifiers, charging ports, or any other feature of the hearing aid component 101. The opening 121 may include a first opening 121a, a second opening 121b, and a third opening 121c. The first, second, and third openings 121a, 121b, and 121c may each surround a central opening 121d. The first, second, and third openings 121a, 121b, and 121c may be configured to expose the microphone or amplifier of the hearing aid component 101 while the central opening 121d may expose a button or other control function of the hearing aid component 101. Ridges 122 may also be disposed adjacent each of the first opening 121a and the third opening 121c to assist and facilitate slidably coupling the first housing member 102 within the second housing member 104 and aligning these two components together. The central opening 121d may be disposed adjacent the lattice portion 112 of the first housing member 102. The central opening 121d may be oval in shape. The central opening 121d may be any shape to accommodate the button of the hearing aid component 101. One of ordinary skill in the art may select a suitable configuration for the one or more openings 121 to accommodate the components of the hearing aid component 101 within the scope of the present disclosure.

With reference to FIGS. 1-7, the second housing member 104 may be formed of an inflexible material such as polyethylene terephthalate (PET), thermoplastic polyurethane (TPU), polyamide 11 (PA 11), polyethylene terephthalate glycol (PETG), or any suitable material within the scope of the present disclosure. The inflexible material may be understood to define a hard, stiff, or rigid material with minimal flexibility or pliability. The inflexible material of the second housing member 104 is understood to be less flexible than the flexible material of the first housing member 102. The hardness of the inflexible material may allow the second housing member 104 to protect the hearing aid component 101 and militate against damage to the hearing aid component 101. One of ordinary skill in the art may select any inflexible material to form the second housing member 104 within the scope of the present disclosure.

The second housing member 104 may include a first end 128 and a second end 130. Each of the first end 128 and the second end 130 may be open ends forming a second channel 132 between the first end 128 and the second end 130. The first end 128 and the second end 130 may allow the first housing member 102 with the hearing aid component 101 within the first housing member 102 to be slidably received in the second channel 132 of the second housing member 104. The second housing member 104 may similarly include interior dimensions that are substantially equal to exterior dimensions of the first housing member 102 to allow the first housing member 102 to be received within the second channel 132 of the second housing member 104. The first end 128 may be larger or greater in one or more dimensions than the corresponding dimensions of the second end 130, thereby facilitating the first housing member to be slidably received withing the second housing member 104 from the first end 128 until contacting the second end 130. More specifically, the first end 128 may include a larger diameter than a diameter of the second end 130, allowing the first housing member 102 to be slidably received through the first end 128 and to allow the second end 130 to militate against the first housing member 102 from sliding out of the second end 130 for secure coupling thereof. The second housing member 104 may include interior dimensions substantially equal to exterior dimensions of the first housing member 102 for providing the secure coupling thereto. The second housing member 104 may also be customized to accommodate a shape of each of the first housing member 102, the hearing aid component 101, and the ear of the individual for comfort.

The second housing member 104 may also include one or more holes 131. The hole 131 may be configured to expose a feature or component of the hearing aid component 101 including a button, a speaker, a microphone, audible receiver, amplifiers, charging ports, or any other feature of the hearing aid component 101. The second housing member 104 may include one or more holes 131 to accommodate exposure to the features of each of the first housing member 102 and the hearing aid component 101 within the scope of the present disclosure. The hole 131 may include a first hole 131a, a second hole 131b, and a third hole 131c. The first, second, and third holes 131a, 131b, and 131c may each surround a central hole 131d. The central hole 131d may expose a button or other control function of the hearing aid component 101. The central hole 131d may be oval in shape. The central hole 131d may be any shape to accommodate the button of the hearing aid component 101. Each of the holes 131 of the second housing member 104 may be configured to be aligned with respective openings 121 of the first housing member 102 to expose the components and features of the hearing aid component 101 and militate against blocking of sound, access, and/or functionality of the hearing aid component 101. One of ordinary skill in the art may select a suitable configuration for the hole 131 to accommodate the components of the hearing aid component 101 within the scope of the present disclosure. It should be appreciated that the second housing member 104 may be configured in a similar configuration to the first housing member 102 to accommodate the hearing aid component 101 such that holes 131 of the second housing member 104 cooperate with the openings 121 of the first housing member 102, which may further conform in shape in addition to relative position, thereby allowing access or connection to hearing aid component 101 control functions; e.g., microphone, speaker, buttons, etc.

The second channel 132 may also include an inner surface 134. The inner surface 134 of the second housing member 104 may be lined with a soft material to militate against damage to the outer surface 126 of the first housing member 102 when slidably disposing the first housing member 102 within the second housing member 104. The smooth surface 116 of the first housing member 102 as well as the inner surface 134 of the second channel 132 having a soft material may both assist in slidably disposing the first housing member 102 within the second housing member 104 without damaging the outer surface 126 of the first housing member 102. The soft material militates against scratches to the outer surface 126 as the first housing member 102 is slidably received and removed within the second channel 132 of the second housing member 104. An entirety of the inner surface 134 of the second channel 132 may be lined with the soft material. Alternatively, a portion of the inner surface 134 of the second channel 132 may be lined with the soft material. The soft material may be coupled to the inner surface 134 of the second channel 132 via an adhesive. The soft material may also be permanently coupled or formed integrally to the entirety of the inner surface 134 of the second channel 132. The soft material may alternatively be configured as a separate housing member configured to be disposed within the second channel 132 of the second housing member 104 adjacent the first housing member 102, also configured in a similar shape with similar dimensions to the second housing member 104. The soft material may include microfiber, felt, or foamed polymer. One of ordinary skill in the art may select any suitable soft material to internally line the inner surface 134 of the second channel 132 of the second housing member 104 within the scope of the present disclosure.

Opposite the inner surface 134 of the second housing member 104 is an outer surface 136. The outer surface 136 of the second housing member 104 may also include a smooth continuous surface 136. The outer surface 136 may be free of any surface interruptions or alterations. The outer surface 136 of the second housing member 104 may be configured to rest behind the ear of the individual and may contact the ear of the individual. Desirably, the outer surface 136 may be smooth to provide comfort for the user as the cover 100 sits behind the ear of the individual. The outer surface 136 may also be separated by a second gap 138.

The second gap 138 may be configured as a break or discontinuity of the second housing member 104. The second gap 138 may be configured to align with the first gap 118 of the first housing member 102 for slidably and removably coupling the first housing member 102 to the second housing member 104. The first housing member 102 may be configured to be slidably received in the second housing member 104 by aligning the first gap 118 of the first housing member 102 with the second gap 138 of the second housing member 104. More specifically, the ridges 122 on the inner surface 124 and the outer surface 126 of the first housing member 102 may be configured to align and position the first gap 118 with the second gap 138 of the second housing member 104 for slidably coupling the first housing member 102 to the second housing member 104. The ridges 122 adjacent the first opening 121a and the third opening 121c of the first housing member 102 also assist in facilitating the coupling, aligning, and positioning of the first housing member 102 with the second housing member 104. This ensures that the first housing member 102 is properly aligned with the second housing member 104 to militate against obstructing features of the hearing aid component 101 to maximize functionality of the hearing aid component 101. The ridges 122 may position and align the first housing member 102 with the second housing member 104, ensuring each of the openings 121 and the holes 131 of the first housing member 102 and second housing member 104 as well as the first gap 118 of the first housing member 102 and the second gap 138 of the second housing member 104 are aligned with one another.

It should be appreciated that the first gap 118 of the first housing member 102 and the second gap 138 of the second housing member 104 may define portions of the first housing member 102 and the second housing member 104 which do not meet or touch, creating a discontinuity in the first housing member 102 and the second housing member 104. The discontinuity may also be understood to define a break. Advantageously, this allows each of the first housing member 102 and the second housing member 104 to wrap around the hearing aid component 101 without entirely or fully enclosing the hearing aid component 101 in the first housing member 102 and the second housing member 104 to militate against adding tension or pressure on the hearing aid component 101. This may form an open ended shell or case-like structure configured to be slidably disposed around the hearing aid component 101 to accommodate different shapes, sizes, and configurations of the hearing aid component 101 and militating against any damage to the hearing aid component 101 without fully enclosing the hearing aid component 101. Each of the first gap 118 and the second gap 138 may run along a longitudinal axis of the first housing member 102 and the second housing member 104, respectively, which aligns the first gap 118 with the second gap 138 such that the gaps are positioned parallel to one another.

Each of the first housing member 102 and the second housing member 104 may each be formed with a uniform wall thickness. This uniform wall thickness provides improved structural integrity and may reduce warping as well as production costs. Manufacturing each of the first housing member 102 and the second housing member 104 with uniform wall thickness also creates consistency between the first housing member 102 and the second housing member 104 which allows the first housing member 102 to be slidably received in the second housing member 104. Each of the first housing member 102 and the second housing member 104 may be printed using three-dimensional printing methods, allowing the first housing member 102 and the second housing member 104 to be printed with the uniform wall thickness. One of ordinary skill in the art may select a suitable uniform wall thickness within the scope of the present disclosure based on comfort and wear of each individual as well as customization based on the configuration of the hearing aid component 101.

Each of the first housing member 102 and the second housing member 104 may also include a bean shape. The bean shape may be customized to the shape of the hearing aid component 101, which mimics and accommodates the shape of the ear of the individual. This allows the cover 100 including the first housing member 102 and the second housing member 104 to rest behind the ear of the individual according to the shape of the ear. The first housing member 102 and the second housing member 104 may each include a divot 123, 133, respectively. The divot 123, 133 may be U-shaped to accommodate the hearing aid component 101 being slidably received through the first housing member 102 with the thin tube extending out of each of the first housing member 102 and the second housing member 104 from the first end 106, 128, respectively. The U-shaped divot 123 may be formed with the first end 106 of the first housing member 102 and U-shaped divot 133 may be formed with the first end 128 of the second housing member 104. One of ordinary skill in the art may configure the first housing member 102 and the second housing member 104 in any configuration to accommodate any suitable hearing aid component 101 within the scope of the present disclosure. It should be appreciated that the cover 100 including the first housing member 102 and the second housing member 104 may be customized to the shape of the hearing aid component 101 and the shape of the ear of the individual wearing the hearing aid component 101, allowing the first housing member 102 and the second housing member 104 to be customized and altered accordingly.

Each of the first housing member 102 and the second housing member 104 may also be configured to be snap-fit together. Alternatively, the first housing member 102 may be configured in two pieces configured to snap-fit together and the second housing member 104 may be configured in two pieces configured to snap-fit together. The first housing member 102 and the second housing member 104 may be configured to be coupled together in any suitable configuration within the scope of the present disclosure including adhesives, fasteners, friction fits, interference fits, and combinations thereof.

In certain embodiments, a hearing aid system 200 may be provided, as shown in FIGS. 14-16. The hearing aid system 200 may include the hearing aid component 101, as described herein, as well as the cover 100, as described herein. The first housing member 102 may be configured to house the hearing aid component 101. The hearing aid component 101 may be slidably received through the first end 106 of the first housing member 102 where the thin tube or wire may extend out of the first end 106 of the first housing member 102 and into the earmold of the ear canal of the individual. The first housing member 102 may also be slidably received through the first end 128 of the second housing member 104 where the second housing member 104 may house each of the first housing member 102 with the hearing aid component 101.

In certain embodiments, a method 300 of a protecting the hearing aid component 101 may be provided, as shown in FIG. 17. The method 300 may include a step 302 of providing the hearing aid component 101, as described herein, including where the hearing aid component 101 is configured as a behind-the-ear hearing aid component 101. The method 300 may include a step 304 of providing the cover 100 as described herein, including the first housing member 102 and the second housing member 104. The method 300 may include a step 306 of disposing the behind-the-ear hearing aid component 101 within the first housing member 102. This step 306 may further include slidably disposing the behind-the-ear hearing aid component 101 through the first housing member 102 from the first end 106. The method 300 may include a step 308 of disposing the first housing member 102 with the behind-the-ear hearing aid component 101 within the second housing member 104. This step 308 may include slidably disposing the first housing member 102 with the behind-the-ear hearing aid component 101 through the second housing member 104 from the first end 128 and aligning the first gap 118 of the first housing member 102 with the second gap 138 of the second housing member 104.

The cover 100 may advantageously protect the hearing aid component 101 from damage from the surrounding environment or damage from misuse of the hearing aid component 101. The cover 100 may be configured to protect the hearing aid component 101 from damage to external environments and environmental conditions such as humidity, heat, dust, water, and moisture, by housing the hearing aid component 101 within the cover 100. Desirably, the first housing member 102 and the second housing member 104 may militate against damage to the hearing aid component 101 while maintaining functionality of the hearing aid component 101. Advantageously, the first housing member 102 and the second housing member 104 of the cover 100 may be customized to accommodate a shape of the hearing aid component 101 and a shape of the ear of the individual for comfort. Desirably, each of the at least one hole 131 of the second housing member 104 may be configured to be aligned with the at least one opening 121 of the first housing member 102 to expose the components and features of the hearing aid component 101 and militate against blocking of sound, access, and/or functionality of the hearing aid component 101. Advantageously, the ridges 122 of the first housing member 102 may position and align the first housing member 102 with the second housing member 104, ensuring each of the openings 121 of the first housing member 102 and the holes 131 of the second housing member 104 as well as the first gap 118 of the first housing member 102 and the second gap 138 of the second housing member 104 are aligned with one another, and ensuring that the first housing member 102 is properly aligned with the second housing member 104 to militate against obstructing features of the hearing aid component 101 to maximize and maintain functionality of the hearing aid component 101. Advantageously, the lattice portion 112 may be configured to improve drop protection and shock absorption. The drop protection may be understood to define features of the configuration that protect the hearing aid component 101 from damage if the cover 100 with the hearing aid component 101 were to accidentally be dropped.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. Equivalent changes, modifications and variations of some embodiments, materials, compositions and methods can be made within the scope of the present technology, with substantially similar results.

What is claimed is:

1. A cover for a hearing aid component, comprising:
a first housing member configured to receive the hearing aid component;
a second housing member configured to receive the first housing member with the hearing aid component; and
wherein the first housing member and the second housing member militate against damage to the hearing aid component while maintaining functionality of the hearing aid component.

2. The cover of claim 1, wherein the first housing member is formed from a flexible material, the flexible material including an elastomeric polyurethane (EPU) material.

3. The cover of claim 2, wherein the first housing member includes a first end, a second end, and a first channel disposed between the first end and the second end, the first channel configured for receiving the hearing aid component.

4. The cover of claim 3, wherein the first housing member includes a lattice portion having a plurality of interconnected apertures disposed therethrough a portion of the first housing member.

5. The cover of claim 4, wherein another portion of the first housing member includes a smooth surface.

6. The cover of claim 5, wherein the smooth surface of the first housing member is separated by a first gap in the first housing member.

7. The cover of claim 6, wherein the first gap includes a surface alteration surrounding the first gap, the surface alteration includes a plurality of ridges disposed on each of an inner surface and an outer surface of the first housing member.

8. The cover of claim 7, wherein the second housing member includes a first end, a second end, and a second channel disposed between the first end and the second end, the second channel configured for slidably receiving the first housing member with the hearing aid component.

9. The cover of claim 8, wherein an inner surface of the second channel of the second housing member includes a soft material for contacting the first housing member when the second housing member receives the first housing member.

10. The cover of claim 9, wherein an outer surface of the second housing member is smooth, and separated by a second gap of the second housing member.

11. The cover of claim 10, wherein the first housing member is configured to be slidably received in the second housing member aligning the first gap of the first housing member with the second gap of the second housing member.

12. The cover of claim 1, wherein the second housing member is formed from an inflexible material, the inflexible material including a member selected from a group consisting of: polyethylene terephthalate (PET), thermoplastic polyurethane (TPU), polyamide 11 (PA 11), and polyethylene terephthalate glycol (PETG).

13. The cover of claim 1, wherein:
the first housing member is formed from a flexible material, the flexible material including an elastomeric polyurethane (EPU) material,
the first housing member includes a first end, a second end, and a first channel disposed between the first end and the second end, the first channel configured for receiving the hearing aid component,
the first housing member includes a lattice portion having a plurality of interconnected apertures disposed therethrough a portion of the first housing member,
another portion of the first housing member includes a smooth surface,
the smooth surface of the first housing member is separated by a first gap in the first housing member,
the first gap includes a surface alteration surrounding the first gap, the surface alteration includes a plurality of ridges disposed on each of an inner surface and an outer surface of the first housing member,
the second housing member includes a first end, a second end, and a second channel disposed between the first end and the second end, the second channel configured for slidably receiving the first housing member with the hearing aid component,
an inner surface of the second channel of the second housing member includes a soft material for contacting the first housing member when the second housing member receives the first housing member,
an outer surface of the second housing member is smooth, and separated by a second gap of the second housing member,
the first housing member is configured to be slidably received in the second housing member aligning the first gap of the first housing member with the second gap of the second housing member, and
the second housing member is formed from an inflexible material, the inflexible material including a member selected from a group consisting of: polyethylene terephthalate (PET), thermoplastic polyurethane (TPU), polyamide 11 (PA 11), and polyethylene terephthalate glycol (PETG).

14. A hearing aid system, comprising:
a hearing aid component; and
a cover for the hearing aid component including:
a first housing member configured to receive the hearing aid component,
a second housing member configured to receive the first housing member with the hearing aid component, and
wherein the first housing member and the second housing member militate against damage to the hearing aid component while maintaining functionality of the hearing aid component.

15. The hearing aid system of claim 14, wherein:
the first housing member is formed from a flexible material, the flexible material including an elastomeric polyurethane (EPU) material,
the first housing member includes a first end, a second end, and a first channel disposed between the first end and the second end, the first channel configured for receiving the hearing aid component,
the first housing member includes a lattice portion having a plurality of interconnected apertures disposed therethrough a portion of the first housing member,
another portion of the first housing member includes a smooth surface,
the smooth surface of the first housing member is separated by a first gap in the first housing member,
the first gap includes a surface alteration surrounding the first gap, the surface alteration includes a plurality of ridges disposed on each of an inner surface and an outer surface of the first housing member,
the second housing member includes a first end, a second end, and a second channel disposed between the first end and the second end, the second channel configured for slidably receiving the first housing member with the hearing aid component,
an inner surface of the second channel of the second housing member includes a soft material for contacting the first housing member when the second housing member receives the first housing member,
an outer surface of the second housing member is smooth, and separated by a second gap of the second housing member,
the first housing member is configured to be slidably received in the second housing member aligning the first gap of the first housing member with the second gap of the second housing member, and
the second housing member is formed from an inflexible material, the inflexible material including a member selected from a group consisting of: polyethylene terephthalate (PET), thermoplastic polyurethane (TPU), polyamide 11 (PA 11), and polyethylene terephthalate glycol (PETG)

16. The hearing aid system of claim 15, wherein the first housing member is configured to house and surround a portion of the hearing aid component within the first channel while the second housing member slidably receives the first housing member with the hearing aid component within the second channel of the second housing member.

17. The hearing aid system of claim 16, wherein each of the first housing member and the second housing member includes at least one opening aligned with a component of the hearing aid component.

18. The hearing aid system of claim 17, wherein the hearing aid component includes at least one of a control, a microphone, and an audible receiver, each of the control, the microphone, and the audible receiver configured to be accessible through the at least one opening of the first housing member and the second housing member.

19. The hearing aid system of claim 18, wherein the hearing aid component is a behind-the-ear hearing aid component, a portion of the hearing aid component configured to extend out of the first end of the first housing member and the first end of the second housing member.

20. A method of protecting a hearing aid component, comprising:
providing the hearing aid component, the hearing aid component configured as a behind-the-ear hearing aid component;
providing a cover for the hearing aid component, including:
a first housing member configured to receive the hearing aid component,
a second housing member configured to receive the first housing member with the hearing aid component, and
wherein the first housing member and the second housing member militate against damage to the hearing aid component while maintaining functionality of the hearing aid component;
disposing the behind-the-ear hearing aid component within the first housing member; and
disposing the first housing member with the behind-the-ear hearing aid component within the second housing member.
